(19) United States
(12) Patent Application Publication
(10) Pub. No.: US 2025/0143137 A1
(43) Pub. Date: May 1, 2025

(54) LIGHT EMITTING APPARATUS, IMAGE FORMING APPARATUS, DISPLAY APPARATUS, PHOTOELECTRIC CONVERSION APPARATUS, ELECTRONIC EQUIPMENT, ILLUMINATION APPARATUS, MOVING BODY, AND WEARABLE DEVICE

(71) Applicant: CANON KABUSHIKI KAISHA, Tokyo (JP)

(72) Inventors: YOSHIHARU SAWADA, Oita (JP); KENTARO SUZUKI, Kanagawa (JP)

(21) Appl. No.: 18/921,399

(22) Filed: Oct. 21, 2024

(30) Foreign Application Priority Data
Nov. 1, 2023 (JP) 2023-187902

(51) Int. Cl. H10K 59/80; F21V 3/00; F21Y 115/15; G02B 27/01; G03G 15/04; H04M 1/22; H04N 23/63; H10K 59/95

(52) U.S. Cl. CPC H10K 59/80518; G02B 27/0172; G03G 15/04036; H04M 1/22; H04N 23/63; F21V 3/00; F21Y 2115/15; G02B 2027/0178; H10K 59/95

(57) ABSTRACT

A light emitting apparatus in which pixels are arranged on a substrate is provided. Each pixel includes a first electrode, a second electrode arranged between the first electrode and the substrate, an organic layer containing a light emitting material arranged between the first electrode and the second electrode, a reflective electrode arranged between the second electrode and the substrate, and a contact electrode connecting the second electrode and the reflective electrode. A first insulating portion is arranged between the reflective electrode and the second electrode and a second insulating portion is arranged between the reflective electrodes, and the contact electrode includes a first portion arranged on the second insulating portion, and a second portion extending from the first portion and being in contact with the reflective electrode.

### BACKGROUND OF THE INVENTION

### Field of the Invention

The present invention relates to a light emitting apparatus, an image forming apparatus, a display apparatus, a photoelectric conversion apparatus, electronic equipment, an illumination apparatus, a moving body, and a wearable device.

### Description of the Related Art

Japanese Patent Laid-Open No. 2016-122612 describes an electro-optical apparatus including a light emitting element using an organic electroluminescence (EL) element. Japanese Patent Laid-Open No. 2016-122612 also describes that, since a contact resistance increases when a reflective electrode using Al and copper is directly connected to a pixel electrode using indium tin oxide (ITO), a contact electrode using titanium nitride is arranged between the reflective electrode and the pixel electrode.

### SUMMARY OF THE INVENTION

If the entire contact electrode is arranged in the region of the reflective electrode, the reflective region of the reflective electrode for reflecting light may be decreased. A structure that can ensure the reflective region while the contact electrode is in contact with the reflective electrode is desired.

One aspect of the present disclosure provides a technique advantageous in ensuring the reflective region.

According to some embodiments, a light emitting apparatus in which a plurality of pixels are arranged on a main surface of a substrate, wherein each pixel comprises a first electrode, a second electrode arranged between the first electrode and the main surface, an organic function layer containing a light emitting material arranged between the first electrode and the second electrode, a reflective electrode arranged between the second electrode and the main surface, and the reflective electrode, and a contact electrode connecting the second electrode and the reflective electrode, in a section perpendicular to the main surface, a first insulating portion is arranged between the reflective electrode and the second electrode, and a second insulating portion is arranged between the reflective electrodes of pixels adjacent to each other among the plurality of pixels, and in the section perpendicular to the main surface, the contact electrode includes a first portion arranged on the second insulating portion, and a second portion extending continuously from the first portion and being in contact with the reflective electrode, is provided.

Further features of the present invention will become apparent from the following description of exemplary embodiments (with reference to the attached drawings).

### BRIEF DESCRIPTION OF THE DRAWINGS

FIG. 1 is a plan view showing an arrangement example of a light emitting apparatus according to an embodiment;

FIG. 2 is a sectional view showing an arrangement example of the light emitting apparatus shown in FIG. 1;

FIGS. 3A to 3E are sectional views showing an example of a manufacturing process of the light emitting apparatus shown in FIG. 2;

FIG. 4 is a sectional view showing an arrangement example of a light emitting apparatus of a comparative example;

FIG. 5 is a sectional view showing an arrangement example of the light emitting apparatus shown in FIG. 1;

FIGS. 6A to 6E are sectional views showing an example of a manufacturing process of the light emitting apparatus shown in FIG. 5;

FIGS. 7A and 7B are sectional views showing an arrangement example of the pixel of the light emitting apparatus shown in FIG. 1;

FIGS. 8A to 8C are views showing an example of an image forming apparatus using the light emitting apparatus according to the embodiment;

FIG. 9 is a view showing an example of a display apparatus using the light emitting apparatus according to the embodiment;

FIG. 10 is a view showing an example of a photoelectric conversion apparatus using the light emitting apparatus according to the embodiment;

FIG. 11 is a view showing an example of electronic equipment using the light emitting apparatus according to the embodiment;

FIGS. 12A and 12B are views each showing an example of a display apparatus using the light emitting apparatus according to the embodiment;

FIG. 13 is a view showing an example of an illumination apparatus using the light emitting apparatus according to the embodiment;

FIG. 14 is a view showing an example of a moving body using the light emitting apparatus according to the embodiment; and

FIGS. 15A and 15B are views each showing an example of a wearable device using the light emitting apparatus according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

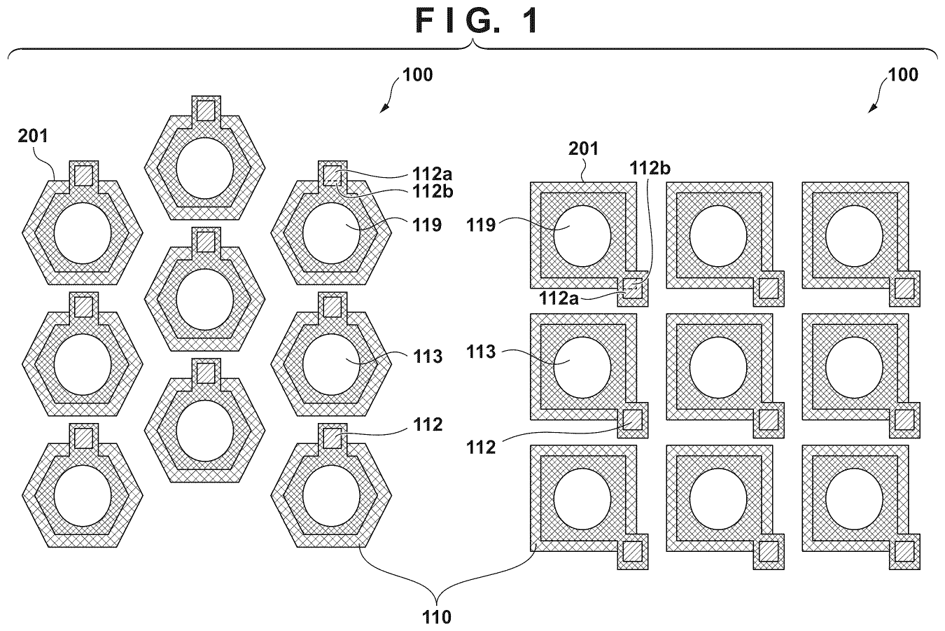

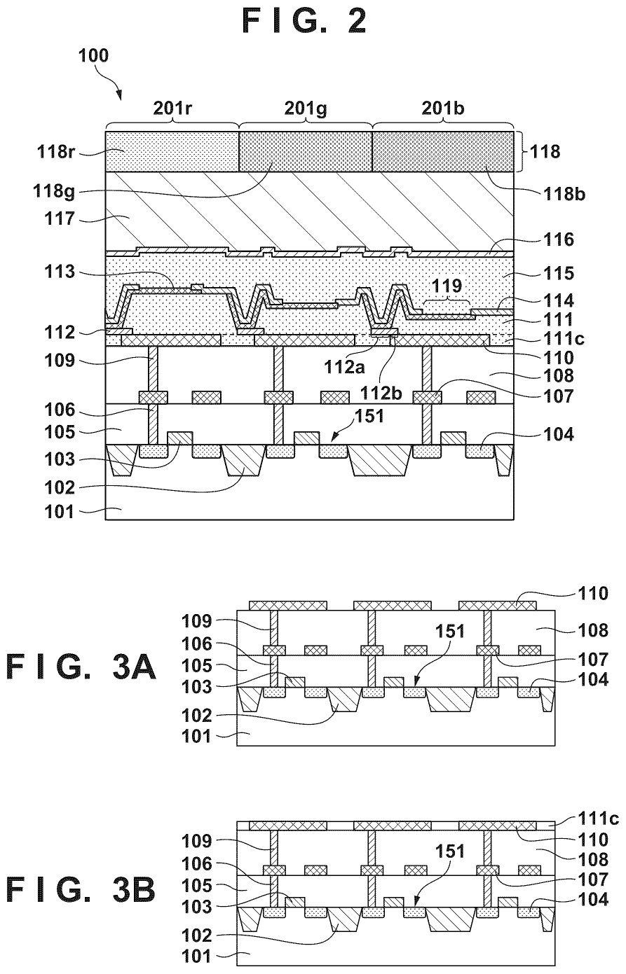

With reference to FIGS. 1 to 6E, a light emitting apparatus according to an embodiment of the present disclosure will be described. The following embodiments are merely examples of the present disclosure and not intended to limit the scope of the invention according to the appended claims. FIG. 1 is a plan view showing an arrangement example of a light emitting apparatus 100 according to the present disclosure. FIG. 2 is a sectional view showing an arrangement example of the light emitting apparatus 100.

The plan view of FIG. 1 shows an arrangement example of a reflective electrode 110, a contact electrode 112, an electrode 113 (to be also referred to as a lower electrode), a light emitting region 119 of a pixel 201 arranged in the light emitting apparatus 100. The shape of the pixel 201 in a planar view may be, for example, hexagonal as shown on the left side of FIG. 1. Alternatively, for example, the shape of the pixel 201 in a planar view may be rectangular as shown on the right side of FIG. 1. The contact electrode 112 is partially in contact with the reflective electrode 110, and extends from the part in contact with the reflective electrode 110 to the outside of the region where the reflective electrode 110 is arranged.

Next, the arrangement of the pixel 201 will be described in detail using the sectional view of FIG. 2. FIG. 2 shows a plurality of pixels 201r, 201g, and 201b arranged above a main surface 151 of a substrate 101. Each pixel 201 includes an electrode 116, the electrode 113 arranged between the electrode 116 and the main surface 151 of the substrate 101, and an organic function layer 115 containing a light emitting material arranged between the electrode 116 and the electrode 113. Each pixel 201 further includes the reflective electrode 110 arranged between the electrode 113 and the main surface 151 of the substrate 101, an insulating layer 111 arranged between the electrode 113 and the reflective electrode 110, and the contact electrode 112 connecting the electrode 113 and the reflective electrode 110.

In the substrate 101, for example, an element isolation region 102 (which may be, for example, an STI structure), a gate insulating film, a gate electrode 103, and a source/drain region 104, which form a transistor for driving the pixel 201, are arranged. The substrate 101 can be a semiconductor substrate using, for example, silicon (Si) or the like. However, the substrate 101 is not limited to this, and may be an insulating substrate of glass, plastic, or the like. In that case, a semiconductor layer made of silicon or the like may be formed on the insulating substrate, and an element such as the transistor may be formed in the semiconductor layer.

An interlayer insulating film 105 is formed between the main surface 151 of the substrate 101 and the reflective electrode 110. Further, a wiring layer 107 is arranged between the interlayer insulating film 105 and the reflective electrode 110. The source/drain region 104 and a wiring pattern arranged in the wiring layer 107 are electrically connected via a conductive plug 106. The gate electrode 103 and a wiring pattern arranged in the wiring layer 107 are similarly electrically connected via a conductive plug. For the interlayer insulating film 105, for example, borophosphosilicate glass (BPSG) deposited using a terminal CVD method, silicon oxide (which is not limited to SiO and may be SiON, SiN, or the like) or the like deposited using a plasma CVD method can be used. For the wiring pattern arranged in the wiring layer 107, aluminum (Al), an alloy of Al and copper (Cu) (for example, Al doped with 0.5 (atm %) of Cu (to be referred to as AlCu)), or the like can be used. A barrier metal such as titanium (Ti)/titanium nitride (TiN) can be arranged in the interface between the wiring pattern formed of AlCu or the like and the interlayer insulating film 105 or 108. Tungsten (W) or the like can be used for the conductive plug 106. A barrier metal such as Ti/TiN can be arranged in the interface between the conductive plug 106 using W and the interlayer insulating film 105.

The interlayer insulating film 108 is arranged to cover the interlayer insulating film 105 and the wiring layer 107. It can also be said that the interlayer insulating film 108 is arranged between the interlayer insulating film 105 (and the wiring layer 107) and the reflective electrode 110. The wiring pattern arranged in the wiring layer 107 and the reflective electrode 110 are electrically connected via a conductive plug 109. For the interlayer insulating film 108, for example, silicon oxide or the like deposited using a plasma CVD method can be used. For the reflective electrode 110, AlCu or the like can be used. For the conductive plug 109, W or the like can be used. A barrier metal such as Ti/TiN can be arranged in the interface between the conductive plug 109 using W and the interlayer insulating film 108. The reflective electrode 110 may be used as a wiring pattern for transmitting an electric signal or the like.

The insulating layer 111 is arranged to cover the reflective electrode 110. The insulating layer 111 can be a layer that is transparent with respect to the light emitted from a light emitting material arranged in the organic function layer 115. For the insulating layer 111, for example, silicon oxide or the like deposited using the plasma CVD method can be used. In a section perpendicular to the main surface 151 of the substrate 101, the insulating layer 111 includes an insulating portion arranged between the reflective electrode 110 and the electrode 113. The insulating layer 111 also includes an insulating portion 111c arranged between the reflective electrodes 110 of the pixels 201 adjacent to each other among the plurality of pixels 201. It can also be said that the insulating portion 111c is arranged to electrically isolate the reflective electrodes 110 respectively arranged in the pixels 201.

The electrode 113 is arranged on the reflective electrode 110. The electrode 113 may function as, for example, an anode electrode. A transparent conductive material is used for the electrode 113. For example, the electrode 113 may be formed using indium tin oxide (ITO) or indium zinc oxide (IZO).

The electrode 113 and the reflective electrode 110 are electrically connected by the contact electrode 112. For example, Ti, molybdenum (Mo), chromium (Cr), or the like can be used for the contact electrode 112. For example, TiN may be used for the contact electrode 112. The contact electrode 112 includes a portion 112a arranged on the insulating portion 111c, and a portion 112b extending continuously from the portion 112a and being in contact with the reflective electrode 110. As shown in FIG. 2, the electrode 113 is in contact with the portion 112a of the contact electrode 112. As shown in FIG. 2, the electrode 113 may not be in contact with the portion 112b of the contact electrode 112. The length of the part of the portion 112b in contact with the reflective electrode 110 may be smaller than twice the length of the part of the electrode 113 in contact with the contact electrode 112. The length of the part of the portion 112b in contact with the reflective electrode 110 may be smaller than the length of the part of the electrode 113 in contact with the contact electrode 112. With this arrangement, the area of the contact electrode 112 arranged on the reflective electrode 110 can be reduced and the reflective region can be increased.

An insulating layer 114 covering the outer edge portion of the electrode 113 and defining the light emitting region 119 of each pixel 201 is arranged on the electrode 113 and between the organic function layer 115 and the electrode 113. For the insulating layer 114, for example, silicon oxide deposited by a plasma CVD method can be used. The insulating layer 114 electrically isolates the electrodes 113 of the respective pixels 201.

The organic function layer 115 at least includes a light emitting layer containing an organic light emitting material. As function layers other than the light emitting layer, the organic function layer 115 may include, for example, a charge transport layer, a charge blocking layer, and the like. The organic function layer 115 may be shared by the plurality of pixels 201 as shown in FIG. 2.

The electrode 116 is arranged to cover the organic function layer 115. The electrode 116 can also be called an upper electrode. The electrode 116 may function as a cathode electrode. In order to emit the light emitted from the organic function layer 115 to the upper surface without blocking it, the electrode 116 may be a thin film of a transparent material. For the electrode 116, gold (Au), platinum (Pt), silver (Ag), Al, Cr, magnesium (Mg), an alloy thereof, or the like may be used. The electrode 116 may be shared by the plurality of pixels 201 as shown in FIG. 2.

A sealing layer 117 is arranged to cover the electrode 116. The sealing layer 117 is arranged to prevent permeation of water and the like into respective layers between the electrode 116 and the substrate 101. For the sealing layer 117, for example, silicon nitride (SiN) or the like deposited using a plasma CVD method can be used.

A color filter 118 is arranged to cover the sealing layer 117. In the arrangement shown in FIG. 2, a color filter 118r, a color filter 118g, and a color filter 118b that transmit colors having different peak wavelengths, respectively, are arranged. The color filter 118r transmits red light, the color filter 118g transmits green light, and the color filter 118b transmits blue light. As shown in FIG. 2, the pixel 201 may have an optical resonance structure whose thickness of the insulating layer 111 between the reflective electrode 110 and the electrode 113 changes in accordance with the wavelength of light transmitted by the color filter 118. More specifically, the peak wavelength of color to be transmitted is different between the color filter 118r of the pixel 201r and the color filter 118g of the pixel 201g (between the color filter 118r of the pixel 201r and the color filter 118b of the pixel 201b or between the color filter 118g of the pixel 201g and the color filter 118b of the pixel 201b). In this case, the thickness of the portion of the insulating layer 111 overlapping the light emitting region 119 may be different between the pixel 201r and the pixel 201g (between the pixel 201r and the pixel 201b or between the pixel 201g and the pixel 201b).

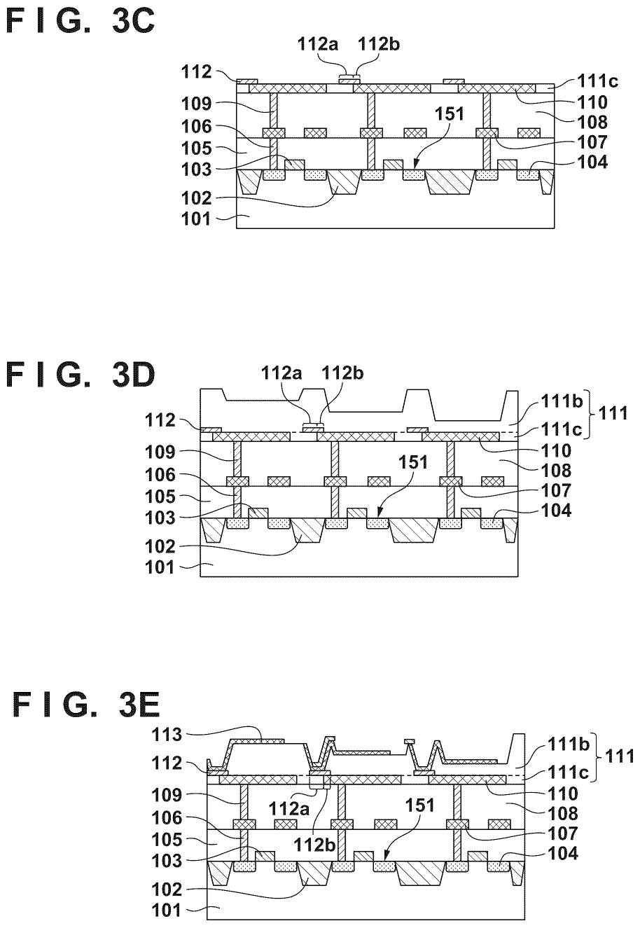

Next, with reference to FIGS. 3A to 3E, a manufacturing method of the light emitting apparatus 100 will be described. FIG. 3A shows a state after a step of forming the reflective electrode 110 ends. To form the reflective electrode 110, for example, AlCu is deposited using a sputtering method. Then, the reflective electrode 110 is formed through a photolithography step, an etching (for example, dry etching) step, and the like.

After the reflective electrode 110 is formed, the insulating portion 111c of the insulating layer 111 is formed. For example, the material layer (for example, SiO) of the insulating portion 111c is deposited to cover the reflective electrode 110 using a high density plasma CVD method. Then, planarization is performed using a CMP method, thereby forming the insulating portion 111c of the insulating layer 111 as shown in FIG. 3B.

Then, the contact electrode 112 is formed. To form the contact electrode 112, for example, TiN is deposited using a sputtering method. Then, the contact electrode 112 is formed through a photolithography step, an etching (for example, dry etching) step, and the like as shown in FIG. 3C. A part (portion 112b) of the formed contact electrode 112 is in contact with a part of the reflective electrode 110 and electrically connected thereto. Since planarization is performed using the CMP method when forming the insulating portion 111c, the portion 112a and portion 112b of the contact electrode 112 are connected flatly.

After the contact electrode 112 is formed, the insulating layer 111b of the insulating layer 111 is deposited. For example, the material layer (for example, SiO) of the insulating layer 111b is deposited using a high density plasma method or the like. Then, the unevenness of the upper surface of the material layer generated due to the unevenness of the underlayer such as the contact electrode 112 is planarized using a CMP method or the like. When the upper surface of the material layer of the insulating layer 111b is planarized, formation of the insulating layer 111b may be ended. Further, as shown in FIG. 3D, the insulating layer 111b may be adjusted to the different thicknesses corresponding to the pixels 201r, 201g, and 201b to implement the optical resonance structure.

Then, as shown in FIG. 3E, the electrode 113 is formed. First, an opening portion for connecting with the contact electrode 112 is formed in the insulating layer 111 using a photolithography step, an etching (for example, dry etching) step, and the like. Then, for example, an ITO film or an IZO film is deposited using a sputtering method or the like, and patterning is performed using a photolithography step, an etching (for example, dry etching) method, and the like to form the electrode 113. As shown in FIG. 3E, the opening portion can be formed in the planarized portion of the upper surface of the material layer of the insulating layer 111b. The contact electrode 112 can be arranged at the same height among the pixels 201. Therefore, the height difference between the portion of the electrode 113 farthest from the main surface 151 and the portion of the contact electrode 112 in contact with the electrode 113 may be the same among the plurality of pixels 201.

Steps before the reflective electrode 110 is formed and steps after the electrode 113 is formed may be similar to those in a known manufacturing process of a light emitting apparatus using an organic light emitting material. Therefore, a description thereof will be omitted here.

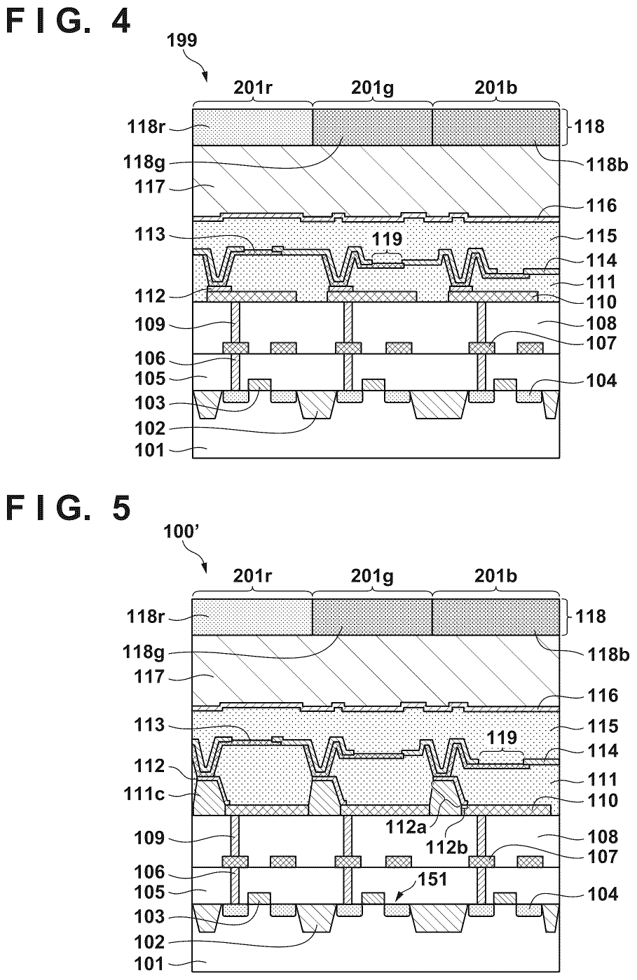

Next, the effect of the present disclosure will be described in comparison with a light emitting apparatus of a comparative example. FIG. 4 is a sectional view showing an arrangement example of a light emitting apparatus 199 of a comparative example. The layer structure of the light emitting apparatus 199 is similar to that of the light emitting apparatus 100 shown in FIG. 2. On the other hand, as in the electro-optical apparatus described in Japanese Patent Laid-Open No. 2016-122612, in the light emitting apparatus 199 of the comparative example, the entire contact electrode 112 is arranged on the reflective electrode 110. Hence, the reflective region of the reflective electrode 110 for reflecting light is small. The reduction in the reflective region can have a negative effect on the improvement of the opening ratio of the pixel 201 and the high resolution of the pixel 201.

To the contrary, in the light emitting apparatus 100 of this embodiment shown in FIG. 2, the contact electrode 112 includes the portion 112a arranged on the insulating portion and the portion 112b in contact with the reflective electrode 110. The portion 112b of the contact electrode 112 may exist in the minimum range as long as it can be electrically connected to the reflective electrode 110. Therefore, the structure of the light emitting apparatus 100 can more easily ensure the reflective region of the reflective electrode 110 for reflecting light. As a result, it can be seen that the light emitting region 119 of the light emitting apparatus 100 shown in FIG. 2 is larger than the light emitting region 119 of the light emitting apparatus 199 of the comparative example shown in FIG. 4. Accordingly, for example, the viewing angle improves and the degree of freedom of layout increases, so that micronization (high resolution) can be achieved.

As shown in FIGS. 1 and 2, in an orthogonal projection to the main surface 151 of the substrate 101, the portion 112a of the contact electrode 112 may be larger than the portion 112b. As has been described above, the portion 112b of the contact electrode 112 may exist in the minimum range as long as it can be electrically connected to the reflective electrode 110. On the other hand, as shown in FIG. 3E, an opening portion is formed in the insulating layer 111 (111b) so that the portion of the contact electrode 112 in contact with the electrode 113 is exposed. Therefore, in consideration of a process margin and the like, the portion 112a of the contact electrode 112 may have a larger area than the portion 112b. The portion 112a of the contact electrode 112 has a small influence on the reflective region of the reflective electrode 110.

FIG. 5 is a sectional view of a light emitting apparatus 100′ as a modification of the light emitting apparatus 100 shown in FIG. 2. The light emitting apparatus 100′ is different from the light emitting apparatus 100 in the shape of the insulating portion 111c. The remaining arrangement may be similar to the arrangement of the light emitting apparatus 100 shown in FIG. 2, so that the different point of the light emitting apparatus 100′ will mainly be described.

In the light emitting apparatus 100 shown in FIG. 2, the upper surface of the insulating portion 111c is arranged at the same height as the upper surface of the reflective electrode 110. This is because the planarization step is included when forming the insulating portion 111c, as shown in FIG. 3B. Hence, the upper surface of the insulating portion 111c can be at the same height as the upper surface of the reflective electrode 110. Depending on the condition of the planarization step, the upper surface of the insulating portion 111c can be arranged at a lower position (near the main surface 151 of the substrate 101) than the upper surface of the reflective electrode 110.

On the other hand, in the light emitting apparatus 100′, as shown in FIG. 5, in the section perpendicular to the main surface 151 of the substrate 101, the upper surface of the insulating portion 111c is farther from the main surface 151 than the upper surface of the reflective electrode 110 in the direction perpendicular to the main surface 151 of the substrate 101. The contact electrode 112 includes the portion 112a arranged on the insulating portion 111c protruding from the upper surface of the reflective electrode 110, and the portion 112b extending continuously from the portion 112a and being in contact with the reflective electrode 110. As shown in FIG. 5, the electrode 113 is in contact with the portion of the contact electrode 112 arranged on the upper surface of the insulating portion 111c. With this, the reflective electrode 110 and the electrode 113 are electrically connected via the contact electrode 112.

As shown in FIG. 5, the insulating portion 111c may have a tapered shape reducing as parting from the main surface 151 of the substrate 101. In the arrangement shown in FIG. 5, the insulating portion 111c does not cover the upper surface of the reflective electrode 110, but the insulating portion 111c may cover the outer edge portion of the reflective electrode 110. In that case, in the orthogonal projection to the main surface 151 of the substrate 101, the portion 112a of the contact electrode 112 is arranged so as not to overlap the light emitting region 119 of the adjacent pixel 201 not in contact with the reflective electrode 110 and the electrode 113. Note that the portion 112a of the contact electrode 112 may be arranged up to the position overlapping the reflective electrode 110 of the adjacent pixel 201 as long as it does not overlap the light emitting region 119. Even in this case, the portion 112a of the contact electrode 112 is not in contact with the reflective electrode 110 and electrode 113 of the adjacent pixel 201.

As has been described above, the electrode 113 is in contact with the portion of the contact electrode 112 arranged on the upper surface of the insulating portion 111c. In this case, the height difference between the upper surface of the insulating portion 111c and the upper surface of the reflective electrode 110 may be equal to or larger than the distance between the reflective electrodes 110 of the pixels 201 adjacent to each other among the plurality of pixels 201. That is, the height of the insulating portion 111c from the upper surface of the reflective electrode 110 may be equal to or larger than the width of the insulating portion 111c between the reflective electrodes 110. The width of the insulating portion 111c between the reflective electrodes 110 is set not to allow a leakage current to flow between the reflective electrodes 110 adjacent to each other. Further, the portion 112a of the contact electrode 112 and the electrode 113 are arranged at a height equal to or larger than the width between the reflective electrodes 110. With this, a leakage current between the contact electrode 112 (electrode 113) and the reflective electrode 110 of the adjacent pixel 201 is suppressed.

In the light emitting apparatus 100 shown in FIG. 2, the contact electrode 112 is arranged on the insulating portion 111c at the same height as the upper surface of the reflective electrode 110. Therefore, considering a leakage current between the contact electrode 112 and the reflective electrode 110 of the adjacent pixel 201, the interval between the pixels 201 (reflective electrodes 110) adjacent to each other needs to be large. On the other hand, in the light emitting apparatus 100′ shown in FIG. 5, since the insulating portion 111c protrudes from the upper surface of the reflective electrode 110, a leakage current between the contact electrode 112 and the reflective electrode 110 of the adjacent pixel 201 can be suppressed in the height direction. As a result, in the light emitting apparatus 100′, the contact electrode 112 can be arranged near the reflective electrode 110 of the adjacent pixel 201 in the orthogonal projection to the main surface 151 of the substrate 101. Accordingly, it is possible to shorten the distance between the pixels 201 (reflective electrodes 110) adjacent to each other, and micronization (high resolution) of the light emitting apparatus 100′ is achieved.

The portion 112a of the contact electrode 112 is arranged on the side surface of the insulating portion 111c in the height direction. Hence, light leakage between the pixels 201 adjacent to each other can be suppressed. That is, the image quality of the light emitting apparatus 100′ can be improved.

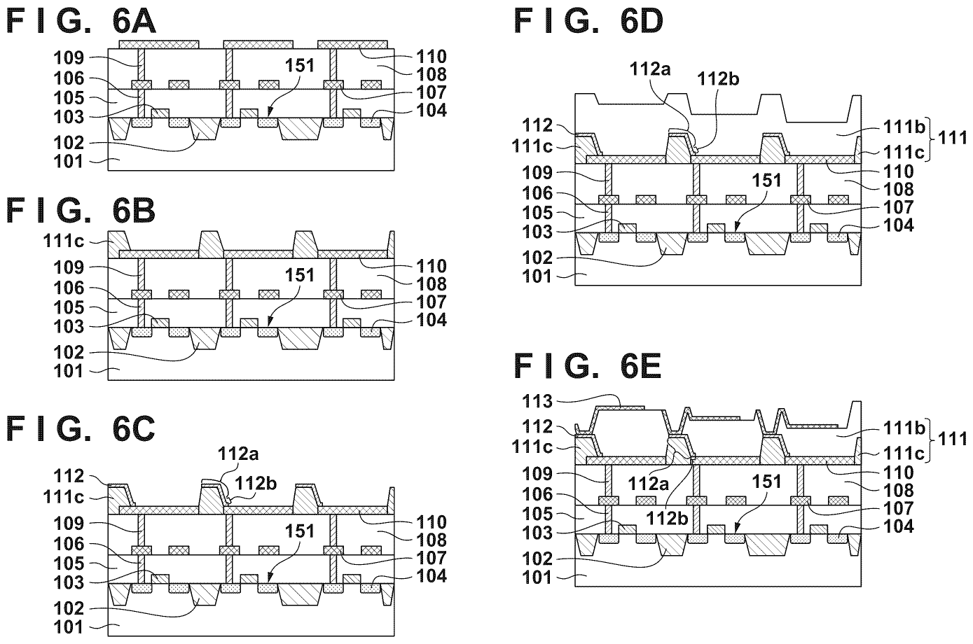

Next, with reference to FIGS. 6A to 6E, a manufacturing method of the light emitting apparatus 100′ will be described. FIG. 6A shows a state after a step of forming the reflective electrode 110 ends. To form the reflective electrode 110, for example, AlCu is deposited using a sputtering method. Then, the reflective electrode 110 is formed through a photolithography step, an etching (for example, dry etching) step, and the like.

Then, as shown in FIG. 6B, the insulating portion 111c of the insulating layer 111 is formed. For example, the material layer (for example, SiO) of the insulating portion 111c is deposited to cover the reflective electrode 110 using a high density plasma CVD method. After the material layer of the insulating portion 111c is formed, planarization is performing using a CMP method. Then, a photolithography step, an etching (for example, dry etching) step, and the like are performed on the planarized material layer to form the insulating portion 111c shown in FIG. 6B. By setting an appropriate condition of the etching step, the tapered shape of the side surface of the insulating portion 111c as shown in FIG. 3B is implemented.

After the insulating portion 111c is formed, the contact electrode 112 is formed. To form the contact electrode 112, for example, TiN is deposited using a sputtering method. Then, the contact electrode 112 is formed through a photolithography step, an etching (for example, dry etching) step, and the like as shown in FIG. 6C. A part (portion 112b) of the formed contact electrode 112 is in contact with a part of the reflective electrode 110 and electrically connected thereto. The portion 112a of the contact electrode 112 is in contact with the side surface and upper surface of the insulating portion 111c from the part connecting to the portion 112b. By making the side surface of the insulating portion 111c in a tapered shape, disconnection between the portions 112a and 112b of the contact electrode 112 and disconnection between the upper surface and side surface of the insulating portion 111c in the portion 112a of the contact electrode 112 can be suppressed.

After the contact electrode 112 is formed, the insulating layer 111b of the insulating layer 111 is deposited. For example, the material layer (for example, SiO) of the insulating layer 111b is deposited using a high density plasma method or the like. Then, the unevenness of the upper surface of the material layer generated due to the unevenness of the underlayer such as the contact electrode 112 is planarized using a CMP method or the like. When the upper surface of the material layer of the insulating layer 111b is planarized, formation of the insulating layer 111b may be ended. Further, as shown in FIG. 6D, the insulating layer 111b may be adjusted to the different thicknesses corresponding to the pixels 201r, 201g, and 201b to implement the optical resonance structure.

Then, as shown in FIG. 6E, the electrode 113 is formed. First, an opening portion for connecting with the contact electrode 112 is formed in the insulating layer 111 using a photolithography step, an etching (for example, dry etching) step, and the like. Then, for example, an ITO film or an IZO film is deposited using a sputtering method or the like, and patterning is performed using a photolithography step, an etching (for example, dry etching) method, and the like to form the electrode 113. The reflective electrode 110 and the electrode 113 are electrically connected via the contact electrode 112.

The electrode 113 may be in contact with the contact electrode 112 in the part of the portion 112a of the contact electrode 112 arranged on the upper surface of the insulating portion 111c. Also in the arrangement shown in FIGS. 5 and 6E, as in the arrangement shown in FIG. 2, the electrode 113 is in contact with the portion 112a of the contact electrode 112 but not in contact with the portion 112b.

Steps before the reflective electrode 110 is formed and steps after the electrode 113 is formed may be similar to those in a known manufacturing process of a light emitting apparatus using an organic light emitting material. Therefore, a description thereof will be omitted here.

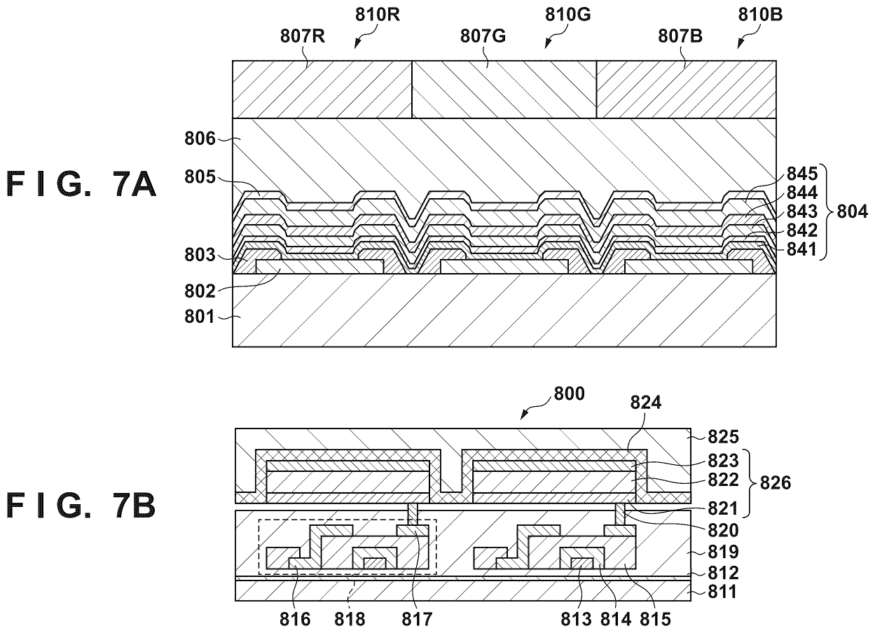

Here, application examples in which the light emitting apparatus 100 or 100′ according to this embodiment is applied to an image forming apparatus, a display apparatus, a photoelectric conversion apparatus, electronic equipment, an illumination apparatus, a moving body, and a wearable device will be described with reference to FIGS. 7A to 15B. The description will be given assuming that, for example, an organic light emitting element such as an organic EL element using an organic light emitting material is arranged in the pixel 201 of the light emitting apparatus 100 as has been described above. Details of each component arranged in the pixel 201 of the light emitting apparatus 100 or 100′ described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of detects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting apparatus may include an optical member such as a microlens on the light emission side. The microlens can be made of acrylic resin, epoxy resin, or the like. The microlens can aim to increase the amount of light extracted from the organic light emitting apparatus and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting apparatus. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting apparatus can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting apparatus includes a display region and a peripheral region arranged around the display region. The light emitting apparatus includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting apparatus includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display apparatus or an illumination apparatus. In addition, the organic light emitting element is applicable to the exposure light source of an electrophotographic image forming apparatus, the backlight of a liquid crystal display apparatus, a light emitting apparatus including a color filter in a white light source, and the like.

The display apparatus may be an image information processing apparatus that includes an image input unit for inputting image information from an area CCD, a linear CCD, a memory card, or the like, and an information processing unit for processing the input information, and displays the input image on a display unit.

In addition, a display unit included in an image capturing apparatus or an inkjet printer can have a touch panel function. The driving type of the touch panel function may be an infrared type, a capacitance type, a resistive film type, or an electromagnetic induction type, and is not particularly limited. The display apparatus may be used for the display unit of a multifunction printer.

More details will be described next with reference to the accompanying drawings. FIG. 7A shows an example of the pixel 201 arranged in the light emitting apparatus 100 or 100′. The pixel includes sub-pixels 810 (pixels 201). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display apparatus 800 (corresponding to the above-described light emitting apparatus 100 or 100′) shown in FIG. 7B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 7B. That is, one of the anode and cathode and one of the source electrode and drain electrode of the TFT are electrically connected. The TFT indicates a thin-film transistor.

In the display apparatus 800 shown in FIG. 7B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display apparatus 800 shown in FIG. 7B but may be used as another switching element.

The transistor used in the display apparatus 800 shown in FIG. 7B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display apparatus 800 shown in FIG. 7B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

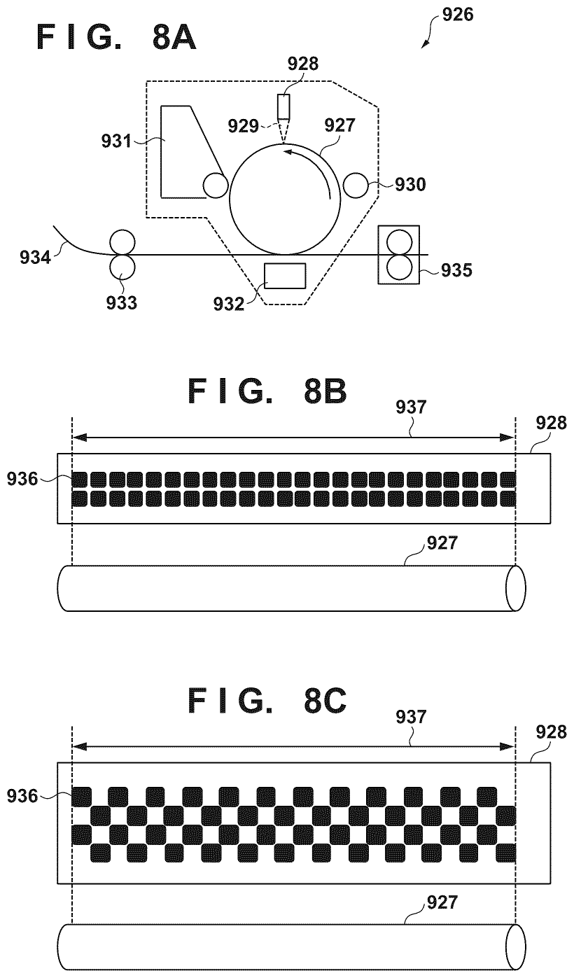

FIGS. 8A to 8C are schematic views showing an example of an image forming apparatus using the light emitting apparatus 100 according to this embodiment. An image forming apparatus 926 shown in FIG. 8A includes a photosensitive member 927, an exposure light source 928, a developing unit 931, a charging unit 930, a transfer device 932, a conveyance unit 933 (a conveyance roller in the arrangement shown in FIG. 8A), and a fixing apparatus 935.

Light 929 is emitted from the exposure light source 928, and an electrostatic latent image is formed on the surface of the photosensitive member 927. The light emitting apparatus 100 or 100′ can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing apparatus 935 fixes the image formed on the print medium.

Each of FIGS. 8B and 8C is a schematic view showing a form in which a plurality of light emitting units 936 are arranged in the exposure light source 928 along the longitudinal direction of a long substrate. The light emitting apparatus 100 or 100′ can be applied to each of the light emitting units 936. That is, a plurality of the pixels 201 are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 8B shows a form in which the light emitting units 936 are arranged along the long-axis direction of the photosensitive member 927. FIG. 8C shows a form, which is a modification of the arrangement of the light emitting units 936 shown in FIG. 8B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 8C can be referred to as, for example, an arrangement in a grid pattern, an arrangement in a staggered pattern, or an arrangement in a checkered pattern.

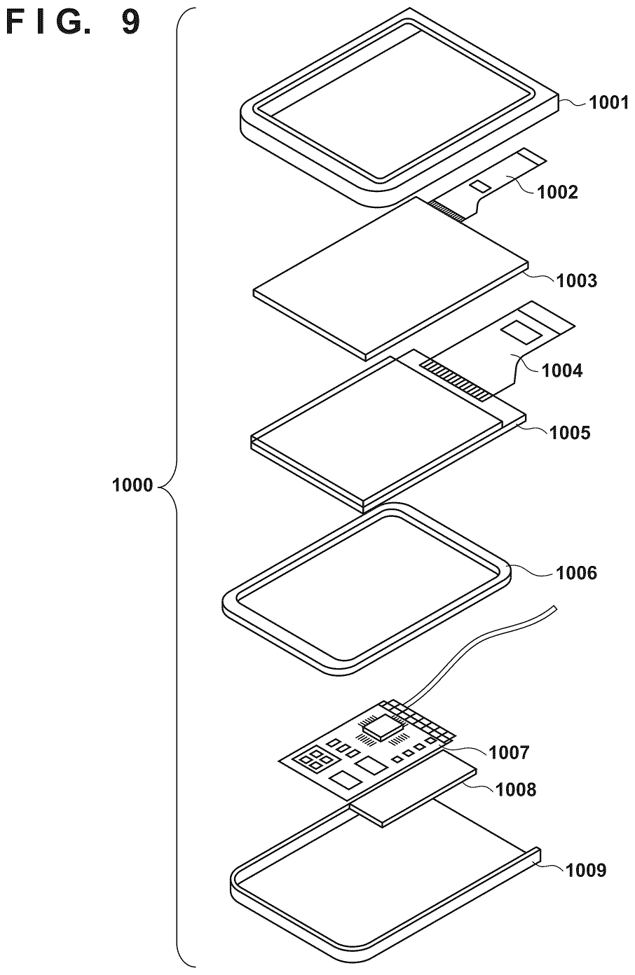

FIG. 9 is a schematic view showing an example of the display apparatus using the light emitting apparatus 100 or 100′ according to this embodiment. A display apparatus 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display apparatus 1000 is not portable equipment. Even when the display apparatus 1000 is portable equipment, the battery 1008 need not be provided at this position. The light emitting apparatus 100 or 100′ can be applied to the display panel 1005. The pixels 201 arranged in the light emitting apparatus 100 or 100′ functioning as the display panel 1005 operate in a state in which they are connected to the active elements such as transistors arranged on the circuit board 1007.

The display apparatus 1000 shown in FIG. 9 can be used for a display unit of a photoelectric conversion apparatus (also referred to as an image capturing apparatus) including an optical unit having a plurality of lenses, and an image sensor for receiving light having passed through the optical unit and photoelectrically converting the light into an electric signal. The photoelectric conversion apparatus can include a display unit for displaying information acquired by the image sensor. In addition, the display unit can be either a display unit exposed outside the photoelectric conversion apparatus, or a display unit arranged in the finder. The photoelectric conversion apparatus can be a digital camera or a digital video camera.

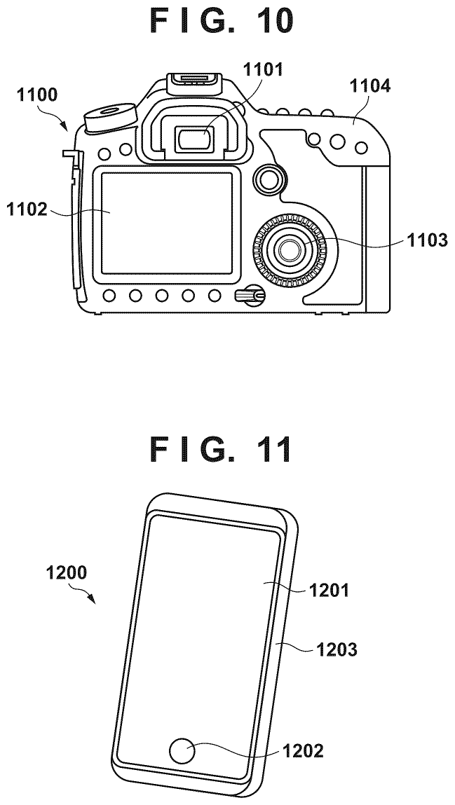

FIG. 10 is a schematic view showing an example of the photoelectric conversion apparatus using the light emitting apparatus 100 or 100′ according to this embodiment. A photoelectric conversion apparatus 1100 can include a viewfinder 1101, a rear display 1102, an operation unit 1103, and a housing 1104. The photoelectric conversion apparatus 1100 can also be called an image capturing apparatus. The light emitting apparatus 100 or 100′ according to this embodiment can be applied to the viewfinder 1101 or the rear display 1102 as a display unit. In this case, the light emitting apparatus 100 or 100′ can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting apparatus 100 or 100′ in which the pixel 201 including the light emitting element using the organic light emitting material such as an organic EL element is arranged may be used for the viewfinder 1101 or the rear display 1102. This is so because the organic light emitting material has a high response speed. The light emitting apparatus 100 or 100′ using the organic light emitting material can be used for the apparatuses that require a high display speed more suitably than for the liquid crystal display apparatus.

The photoelectric conversion apparatus 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting apparatus 100 or 100′ may be applied to a display unit of electronic equipment. At this time, the display unit can have both a display function and an operation function. Examples of the portable terminal are a portable phone such as a smartphone, a tablet, and a head mounted display.

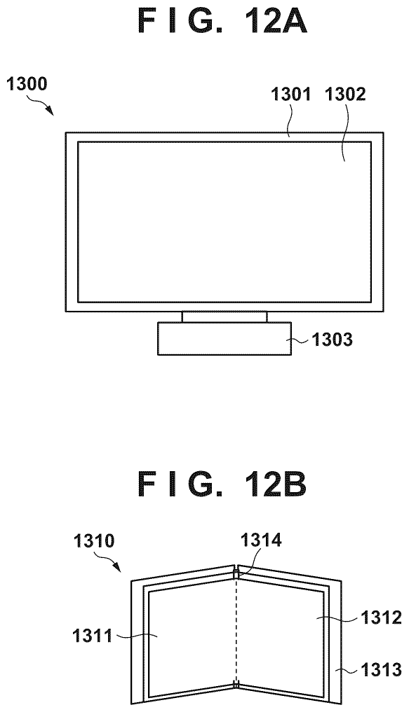

FIG. 11 is a schematic view showing an example of electronic equipment using the light emitting apparatus 100 or 100′ according to this embodiment. Electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable equipment including the communication unit can also be regarded as communication equipment. The light emitting apparatus 100 or 100′ according to this embodiment can be applied to the display unit 1201.

FIGS. 12A and 12B are schematic views showing examples of the display apparatus using the light emitting apparatus 100 or 100′ according to this embodiment. FIG. 12A shows a display apparatus such as a television monitor or a PC monitor. A display apparatus 1300 includes a frame 1301 and a display unit 1302. The light emitting apparatus 100 or 100′ according to this embodiment can be applied to the display unit 1302. The display apparatus 1300 can include a base 1303 that supports the frame 1301 and the display unit 1302. The base 1303 is not limited to the form shown in FIG. 12A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 12B is a schematic view showing another example of the display apparatus using the light emitting apparatus 100 or 100′ according to this embodiment. A display apparatus 1310 shown in FIG. 12B can be folded, and is a so-called foldable display apparatus. The display apparatus 1310 includes a first display unit 1311, a second display unit 1312, a housing 1313, and a bending point 1314. The light emitting apparatus 100 or 100′ according to this embodiment can be applied to each of the first display unit 1311 and the second display unit 1312. The first display unit 1311 and the second display unit 1312 can also be one seamless display apparatus. The first display unit 1311 and the second display unit 1312 can be divided by the bending point. The first display unit 1311 and the second display unit 1312 can display different images, and can also display one image together.

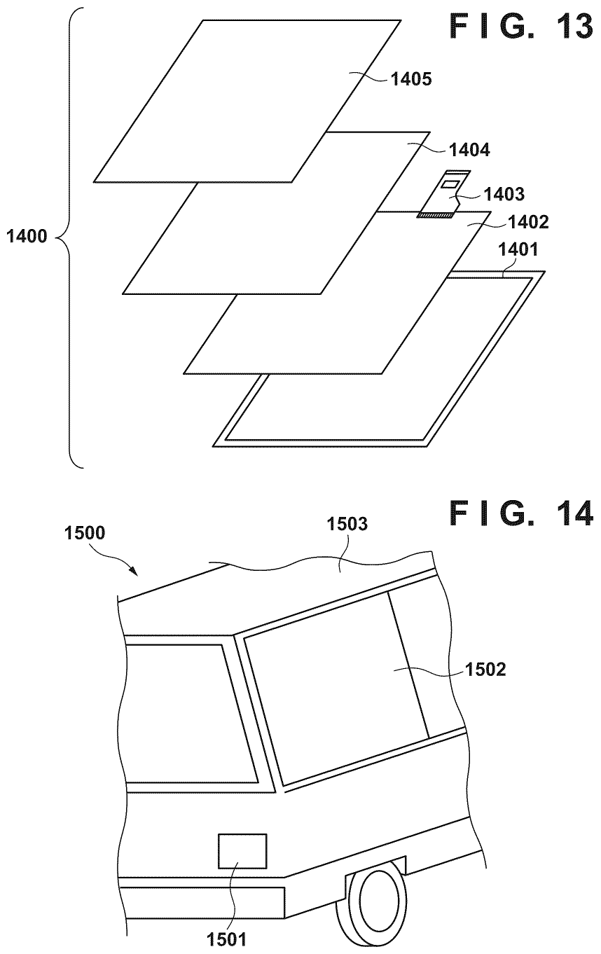

FIG. 13 is a schematic view showing an example of the illumination apparatus using the light emitting apparatus 100 or 100′ according to this embodiment. An illumination apparatus 1400 can include a housing 1401, a light source 1402, a circuit board 1403, an optical film 1404, and a light diffusing unit 1405. The light emitting apparatus 100 or 100′ according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination apparatus can also include a cover on the outermost portion, as needed. The illumination apparatus 1400 can include both or one of the optical film 1404 and the light diffusing unit 1405.

The illumination apparatus 1400 is, for example, an apparatus for illuminating the interior of the room. The illumination apparatus 1400 can emit white light, natural white light, or light of any color from blue to red. The illumination apparatus 1400 can also include a light control circuit for controlling these light components. The illumination apparatus 1400 can also include a power supply circuit connected to the light emitting apparatus 100 or 100′ functioning as the light source 1402. The power supply circuit is a circuit for converting an AC voltage into a DC voltage. White has a color temperature of 4,200 K, and natural white has a color temperature of 5,000 K. The illumination apparatus 1400 may also include a color filter. In addition, the illumination apparatus 1400 can include a heat radiation unit. The heat radiation unit radiates the internal heat of the apparatus to the outside of the apparatus, and examples are a metal having a high specific heat and liquid silicon.

FIG. 14 is a schematic view of an automobile having a taillight as an example of a vehicle lighting appliance using the light emitting apparatus 100 or 100′ according to this embodiment. An automobile 1500 has a taillight 1501, and can have a form in which the taillight 1501 is turned on when performing a braking operation or the like. The light emitting apparatus 100 or 100′ according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting apparatus 100 or 100′ according to this embodiment can be applied to the taillight 1501. The taillight 1501 can include a protection member for protecting the light emitting apparatus 100 or 100′ functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting apparatus 100 or 100′ according to this embodiment may be used. In this case, the constituent materials of the electrodes and the like of the light emitting apparatus 100 or 100′ are formed by transparent members.

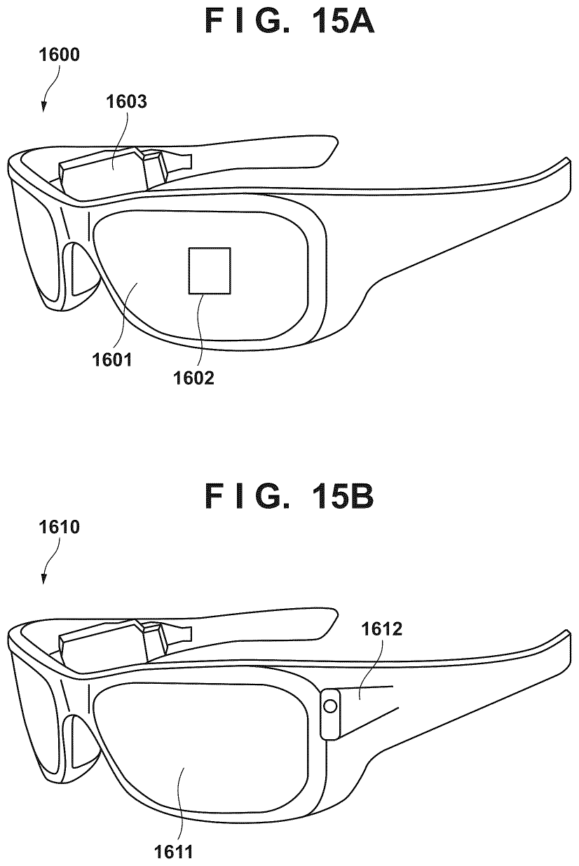

Further application examples of the light emitting apparatus 100 or 100′ according to this embodiment will be described with reference to FIGS. 15A and 15B. The light emitting apparatus 100 or 100′ can be applied to a system that can be worn as a wearable device such as smartglasses, a Head Mounted Display (HMD), or a smart contact lens. An image capturing display apparatus used for such application examples includes an image capturing apparatus capable of photoelectrically converting visible light and a light emitting apparatus capable of emitting visible light.

Glasses 1600 (smartglasses) according to one application example will be described with reference to FIG. 15A. An image capturing apparatus 1602 such as a CMOS sensor or an SPAD is provided on the surface side of a lens 1601 of the glasses 1600. In addition, the light emitting apparatus 100 or 100′ according to this embodiment is provided on the back surface side of the lens 1601. The glasses 1600 further include a control apparatus 1603. The control apparatus 1603 functions as a power supply that supplies electric power to the image capturing apparatus 1602 and the light emitting apparatus 100 or 100′ according to each embodiment. In addition, the control apparatus 1603 controls the operations of the image capturing apparatus 1602 and the light emitting apparatus 100 or 100′. An optical system configured to condense light to the image capturing apparatus 1602 is formed on the lens 1601.

Glasses 1610 (smartglasses) according to one application example will be described with reference to FIG. 15B. The glasses 1610 include a control apparatus 1612, and an image capturing apparatus corresponding to the image capturing apparatus 1602 and the light emitting apparatus 100 or 100′ are mounted on the control apparatus 1612. The image capturing apparatus in the control apparatus 1612 and an optical system configured to project light emitted from the light emitting apparatus 100 or 100′ are formed in a lens 1611, and an image is projected to the lens 1611. The control apparatus 1612 functions as a power supply that supplies electric power to the image capturing apparatus and the light emitting apparatus 100 or 100′, and controls the operations of the image capturing apparatus and the light emitting apparatus 100 or 100′. The control apparatus 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting apparatus 100 or 100′ according to the embodiment of the present disclosure can include an image capturing apparatus including a light receiving element, and control a displayed image based on the line-of-sight information of the user from the image capturing apparatus.

More specifically, the light emitting apparatus 100 or 100′ decides a first visual field region at which the user is gazing and a second visual field region other than the first visual field region based on the line-of-sight information. The first visual field region and the second visual field region may be decided by the control apparatus of the light emitting apparatus 100 or 100′, or those decided by an external control apparatus may be received. In the display region of the light emitting apparatus 100 or 100′, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control apparatus of the light emitting apparatus 100 or 100′, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting apparatus 100 or 100′, the image capturing apparatus, or an external apparatus. If the external apparatus holds the AI program, it is transmitted to the light emitting apparatus 100 or 100′ via communication.

When performing display control based on line-of-sight detection, smartglasses further including an image capturing apparatus configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-187902, filed Nov. 1, 2023, which is hereby incorporated by reference herein in its entirety.

What is claimed is:

1. A light emitting apparatus in which a plurality of pixels are arranged on a main surface of a substrate, wherein
each pixel comprises a first electrode, a second electrode arranged between the first electrode and the main surface, an organic function layer containing a light emitting material arranged between the first electrode and the second electrode, a reflective electrode arranged between the second electrode and the main surface, and a contact electrode connecting the second electrode and the reflective electrode,
in a section perpendicular to the main surface, a first insulating portion is arranged between the reflective electrode and the second electrode, and a second insulating portion is arranged between the reflective electrodes of pixels adjacent to each other among the plurality of pixels, and
in the section perpendicular to the main surface, the contact electrode includes a first portion arranged on the second insulating portion, and a second portion extending continuously from the first portion and being in contact with the reflective electrode.

2. The apparatus according to claim 1, wherein the second electrode is in contact with the first portion.

3. The apparatus according to claim 1, wherein the second electrode is not in contact with the second portion.

4. The apparatus according to claim 1, wherein in an orthogonal projection to the main surface, the first portion is larger than the second portion.

5. The apparatus according to claim 1, wherein in a section perpendicular to the main surface and passing through the reflective electrode, the second insulating portion, the contact electrode, and the second electrode, a length of a part of the second portion in contact with the reflective electrode is smaller than twice a length of a part of the second electrode in contact with the contact electrode.

6. The apparatus according to claim 1, wherein in a section perpendicular to the main surface and passing through the reflective electrode, the second insulating portion, the contact electrode, and the second electrode, a length of a part of the second portion in contact with the reflective electrode is smaller than a length of a part of the second electrode in contact with the contact electrode.

7. The apparatus according to claim 1, wherein
each pixel further comprises, between the organic function layer and the second electrode, an insulating layer covering an outer edge portion of the second electrode and defining a light emitting region of each pixel,
the plurality of pixels include a first pixel and a second pixel, and
the first pixel and the second pixel are different in a thickness of a portion, among the first insulating portion and the second insulating portion, overlapping the light emitting region.

8. The apparatus according to claim 7, wherein
each pixel further comprises a color filter, and
a peak wavelength of a color to be transmitted is different between the color filter of the first pixel and the color filter of the second pixel.

9. The apparatus according to claim 1, wherein a height difference between a portion of the second electrode farthest from the main surface and a portion of the contact electrode in contact with the second electrode is the same among the plurality of pixels.

10. The apparatus according to claim 1, wherein the first portion and the second portion are connected flatly.

11. The apparatus according to claim 1, wherein in the section, an upper surface of the second insulating portion is farther from the main surface than an upper surface of the reflective electrode in a direction perpendicular to the main surface.

12. The apparatus according to claim 11, wherein
the second electrode is in contact with a portion of the contact electrode arranged on the upper surface of the second insulating portion.

13. The apparatus according to claim 11, wherein a height difference between the upper surface of the second insulating portion and the upper surface of the reflective electrode is not less than a distance between the reflective electrodes of pixels adjacent to each other among the plurality of pixels.

14. The apparatus according to claim 11, wherein the second insulating portion has a tapered shape reducing as parting from the main surface.

15. The apparatus according to claim 1, wherein
the second electrode contains a transparent conductive material,
the reflective electrode contains aluminum, and
the contact electrode contains titanium.

16. An image forming apparatus comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes the light emitting apparatus according to claim 1.

17. A display apparatus comprising the light emitting apparatus according to claim 1, and an active element connected to the light emitting apparatus.

18. A photoelectric conversion apparatus comprising an optical unit including a plurality of lenses, an image sensor configured to receive light having passed through the optical unit, and a display unit configured to display an image,
wherein the display unit displays an image captured by the image sensor, and includes the light emitting apparatus according to claim 1.

19. Electronic equipment comprising a housing provided with a display unit, and a communication unit provided in the housing and configured to perform external communication,
wherein the display unit includes the light emitting apparatus according to claim 1.

20. An illumination apparatus comprising a light source, and at least one of a light diffusing unit and an optical film,
wherein the light source includes the light emitting apparatus according to claim 1.

21. A moving body comprising a main body, and a lighting appliance provided in the main body,
wherein the lighting appliance includes the light emitting apparatus according to claim 1.

22. A wearable device comprising a display apparatus configured to display an image,
wherein the display apparatus includes the light emitting apparatus according to claim 1.
